(19) United States
(12) Patent Application Publication
(10) Pub. No.: US 2012/0069638 A1
(43) Pub. Date: Mar. 22, 2012

(54) SEMICONDUCTOR DEVICE

(75) Inventors: Ryoji MATSUDA, Kanagawa (JP); Motoi Ashida, Kanagawa (JP); Takaharu Tsuji, Kanagawa (JP)

(73) Assignee: RENESAS ELECTRONICS CORPORATION

(21) Appl. No.: 13/188,088

(22) Filed: Jul. 21, 2011

(30) Foreign Application Priority Data
Sep. 21, 2010 (JP) 2010-210640

(51) Int. Cl. G11C 11/02; G11C 7/00

(52) U.S. Cl. 365/158; 365/189.16

(57) ABSTRACT

A semiconductor device which it can accommodate variations in a write current threshold in each memory cell and can secure a write margin is provided. An MRAM device includes an MTJ memory cell arranged in a matrix, plural bit lines each arranged corresponding to a memory cell column, plural digit lines each arranged corresponding to a memory cell row, and a write current adjusting unit which adjusts a current amount of a write current to be flowed through a bit line and/or a digit line, in order to perform a data write to each MTJ memory cell normally. The write current adjusting unit divides the plural bit lines and/or the plural digit lines into units of at least one write current line as division units, and includes plural write current adjusting circuits which adjust the current amount of write current in each of the division units.

### CROSS-REFERENCE TO RELATED APPLICATIONS

The disclosure of Japanese Patent Application No. 2010-210640 Filed on Sep. 21, 2010 including the specification, drawings and abstract is incorporated herein by reference in its entirety.

### BACKGROUND

The present invention relates to a semiconductor device including a nonvolatile memory device, more specifically, relates to tuning of data write current in a Magnetic Random Access Memory (MRAM).

A magnetic random access memory (MRAM) device is a memory device provided with an element which has tunnel magnetic resistance (TMR) effect as a memory cell (the element is called henceforth a “tunneling magnetoresistive element”). The MRAM device includes plural memory cells each of which is aligned at a crossing portion of a bit line and a digit line. The tunneling magnetoresistive element has magnetic tunnel junction structure, and includes a first magnetic layer of which the magnetic direction is fixed, a second magnetic layer of which the magnetization direction is rewritable by an externally applied magnetic field, and a tunnel insulating layer sandwiched between the first magnetic layer and the second magnetic layer.

The tunneling magnetoresistive element has the feature that resistance exhibits a minimum and a maximum when the direction of the magnetic moment is parallel and anti-parallel in the first magnetic layer and the second magnetic layer, respectively. Therefore, in the magnetic memory cell which has a tunneling magnetoresistive element (henceforth, also called an “MTJ (Magnetic Tunnel Junction) memory cell”), the parallel state (low resistance state) and the anti-parallel state (high resistance state) of the magnetic moment in the tunneling magnetoresistive elements are associated respectively with logical levels “0” and “1” of stored data. The stored data of an MTJ memory cell is maintained in a nonvolatile manner until it is rewritten by application of a data write magnetic field exceeding a threshold level beyond which the magnetization direction of the magnetic layer can be reversed.

Generally, in an MRAM device, when driving current of a digit line serving as a write current line provided corresponding to a row of an MTJ memory cell, and driving current of a bit line serving as a write current line provided corresponding to a column of the MTJ memory cell exceed a certain threshold value, data writing to the MTJ memory cell can be performed. However, if the driving current of the digit line or the bit line is too large, an MTJ memory cell which is not the write target, such as an MTJ memory cell in a half-selected state, located on either wiring of the bit line or the digit line corresponding to the MTJ memory cell as the write target may malfunction, under the influence of the magnetic field which is originally generated for applying to the MTJ memory cell as the write target.

The threshold of a write current necessary for performing data write to an MTJ memory cell, that is, the threshold of driving currents of a digit line and a bit line, has a variation between MTJ memory cells. Therefore, a method for tuning up the write current is known, so that data write is normally performed to each MTJ memory cell, in other words, so that it is possible to perform the data write to each MTJ memory cell normally and to prevent malfunction of the MTJ memory cell which is not the write target (for example, refer to Japanese Patent Laid-open No. 2007-157206).

### SUMMARY

However, in an MRAM device, a tuning test is generally conducted for the test targets of an MTJ memory cell array including plural MTJ memory cells arranged in a matrix; consequently, write current is set as a current value with which data write can be performed normally to all the memory cells. Accordingly, if an attempt is made to accommodate variations in a threshold of write current of all the MTJ memory cells included in the MTJ memory cell array, setting values of the write current become too large, causing a trouble of affecting MTJ memory cells other than the target MTJ memory cell (henceforth, also called “disturb”). In this way, there arises a problem that a write margin of each MTJ memory cell is narrowed, due to the variations in the characteristics of the MTJ memory cell.

The present invention has been made in view of the above circumstances and provides a semiconductor device including a nonvolatile memory device which can accommodate variations in a write current threshold in each memory cell, and can secure an adequate write margin.

According to one embodiment of the present invention, a semiconductor device includes plural memory cells arranged in a matrix and each able to store data in a nonvolatile manner; plural first write current lines arranged corresponding to columns of the plural memory cells; plural second write current lines arranged corresponding to rows of the plural memory cells; a write current adjusting unit which is able to adjust a current amount of write current to be flowed through the plural first write current lines and/or the plural second write current lines, in order to perform data write normally to each of the plural memory cells; a first write circuit electrically coupled to the plural first write current lines; and a second write circuit electrically coupled to the plural second write current lines. The first write circuit and/or the second write circuit writes data in each of the plural memory cells, by flowing write current through the plural first write current lines and/or the plural second write current lines based on the current amount adjusted by the write current adjusting unit. The write current adjusting unit divides the plural first write current lines and/or the plural second write current lines into units of at least one write current line as division units, and includes plural write current adjusting circuits which is able to adjust the current amount of write current in each of the division units concerned.

According to one embodiment of the present invention, it is possible to accommodate variations in a write current threshold in each memory cell, and to secure an adequate write margin of each memory cell.

### BRIEF DESCRIPTION OF THE DRAWINGS

The present invention will become fully understood from the detailed description given hereinafter and the accompanying drawings, wherein:

FIG. 1 is a schematic block diagram illustrating an entire configuration of an MRAM device as a typical example of a nonvolatile memory device according to an embodiment of the present invention;

FIG. 2 is a schematic diagram illustrating a structure of each MTJ memory cell MC and a data write operation to the MTJ memory cell MC;

FIG. 3 is a block diagram illustrating arrangement of signal wiring used for a data write in an MTJ memory cell array;

FIG. 4 is a drawing illustrating detailed arrangement of normal memory cells, dummy cells, and corresponding signal lines;

FIG. 5 is a circuit diagram illustrating a configuration of a write current adjusting circuit illustrated in FIG. 3;

FIG. 6 is a flow chart explaining a tuning test process of write current;

FIG. 7A, FIG. 7B, and FIG. 7C are conceptual diagrams illustrating the tuning test result of write current;

FIG. 8A, FIG. 8B, and FIG. 8C are drawings explaining a problem in tuning of write current in general;

FIG. 9 is a schematic diagram illustrating a tuning operation of write current according to Embodiment 1 of the present invention;

FIG. 10 is a schematic diagram illustrating a tuning operation of write current according to Modified Example 1 of Embodiment 1 of the present invention;

FIG. 11 is a schematic diagram illustrating an adjusting operation of write current according to Modified Example 2 of Embodiment 1 of the present invention;

FIG. 12 is a schematic diagram illustrating an adjusting operation of write current according to Embodiment 2 of the present invention;

FIG. 13 is a circuit diagram illustrating a configuration of a reference voltage adjusting circuit illustrated in FIG. 12;

FIG. 14 is a schematic diagram illustrating an adjusting operation of write current according to Modified Example 2 of Embodiment 2 of the present invention;

FIG. 15 is a schematic diagram illustrating a tuning operation of write current according to Embodiment 3 of the present invention;

FIG. 16 is a schematic diagram illustrating a tuning operation of write current according to a modified example of Embodiment 3 of the present invention;

FIG. 17 is a schematic diagram illustrating a tuning operation of write current according to Embodiment 4 of the present invention;

FIG. 18 is a drawing illustrating a configuration of one bit line of plural bit lines illustrated in FIG. 17;

FIG. 19 is a schematic diagram illustrating a tuning operation of write current according to a modified example of Embodiment 4 of the present invention;

FIG. 20 is a schematic diagram illustrating a tuning operation of write current according to Embodiment 5 of the present invention;

FIG. 21 is a drawing illustrating a configuration of a self test circuit and explaining a self test;

FIG. 22 is a flow chart explaining a tuning test process of write current by means of the self test circuit illustrated in FIG. 21; and

FIG. 23 is a drawing explaining a modified example of the reference voltage adjusting circuit illustrated in FIG. 13.

### DETAILED DESCRIPTION

Hereinafter, with reference to the accompanying drawings, the embodiments of the present invention are explained in detail. The same symbols will be given to the same portions or the corresponding portions of the drawings, and the explanation thereof is not repeated.

### Embodiment 1

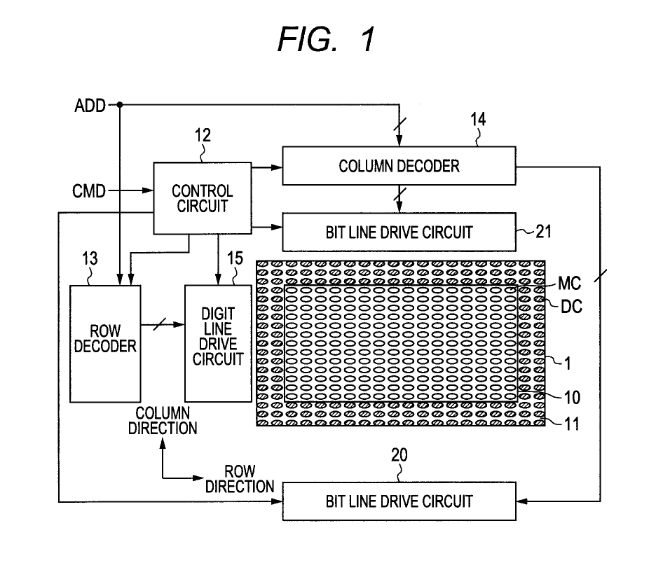

FIG. 1 is a schematic block diagram illustrating an entire configuration of an MRAM device as a typical example of a semiconductor device according to Embodiment 1 of the present invention.

As illustrated in FIG. 1, the MRAM device according to the present embodiment has an MTJ memory cell array 10 in which MTJ memory cells MC for executing data storage are arranged in a matrix. Henceforth, in the present specification, in order to distinguish from a dummy cell explained later, an MTJ memory cell which is arranged in the MTJ memory cell array 10 and becomes as an accessing target in response to an address signal ADD is especially called a “normal memory cell.”

The MRAM device further includes a control circuit 12 which controls entire operation of the MRAM device in response to a control signal CMD, a row decoder 13 which decodes a row address given by the address signal ADD and makes a row selection of a normal memory cell, a column decoder 14 which decodes a column address given by the address signal ADD and makes a column selection of the normal memory cell, and a digit line drive circuit 15 and bit line drive circuits 20 and 21 which control supply of write current.

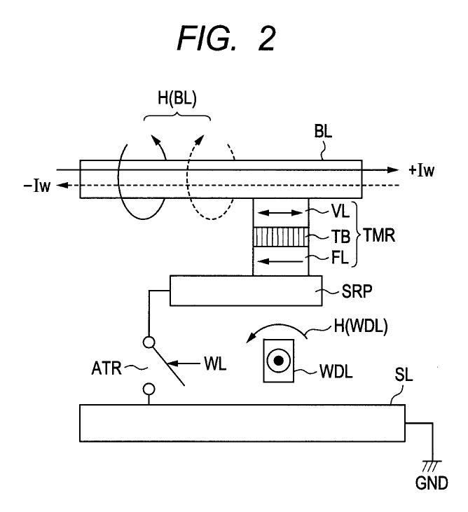

FIG. 2 is a schematic diagram illustrating a structure of each MTJ memory cell MC and a data write operation to the MTJ memory cell MC.

As illustrated in FIG. 2, the MTJ memory cell MC includes a tunneling magnetoresistive element TMR and an access transistor ATR. In the tunneling magnetoresistive element TMR, electric resistance changes corresponding to a data level of stored data written in magnetically.

The access transistor ATR is coupled to the tunneling magnetoresistive element TMR in series between a bit line BL and a source line SL. Typically, a field effect transistor is applied as the access transistor ATR.

As wiring which exerts a direct influence to the MTJ memory cell MC, the followings are provided: a digit line DL for flowing write current at the time of a data write and a data read, a word line WL for instructing a data read, and the source line SL for pulling down the tunneling magnetoresistive element TMR to a ground voltage GND at the time of a data read.

The tunneling magnetoresistive element TMR has a magnetic layer FL which has a fixed magnetization direction (henceforth also simply called a fixed magnetic layer), and a magnetic layer VL which is magnetized in the direction corresponding to a data write magnetic field produced by a write current (henceforth also simply called a free magnetic layer). Between the fixed magnetic layer FL and the free magnetic layer VL, a tunnel barrier TB formed by an insulation layer is provided. The free magnetic layer VL is magnetized in the same direction or in the opposite direction (in the positive direction or in the negative direction) with respect to the fixed magnetic layer FL, corresponding to the level of stored data to be written.

The electric resistance of the tunneling magnetoresistive element TMR changes with the relative relation of the magnetization direction between the fixed magnetic layer FL and the free magnetic layer VL. Specifically, when the magnetization direction is the same between the fixed magnetic layer FL and the free magnetic layer VL, the electric resistance becomes small, compared with a case where the magnetization direction is opposite between them.

In a lower layer of the tunneling magnetoresistive element TMR, a strap SRP (lower electrode) formed by conductive material is placed for securing electric coupling between the tunneling magnetoresistive element TMR and the access transistor ATR.

At the time of a data write, the word line WL is deactivated and the access transistor ATR is turned off. In this state, a write current for magnetizing the free magnetic layer VL is flowed in the direction corresponding to the level of write data in each of the bit line BL and the digit line DL. That is, the magnetization direction of the free magnetic layer VL is determined by the direction of the write current which flows through the bit line BL and the digit line DL, respectively.

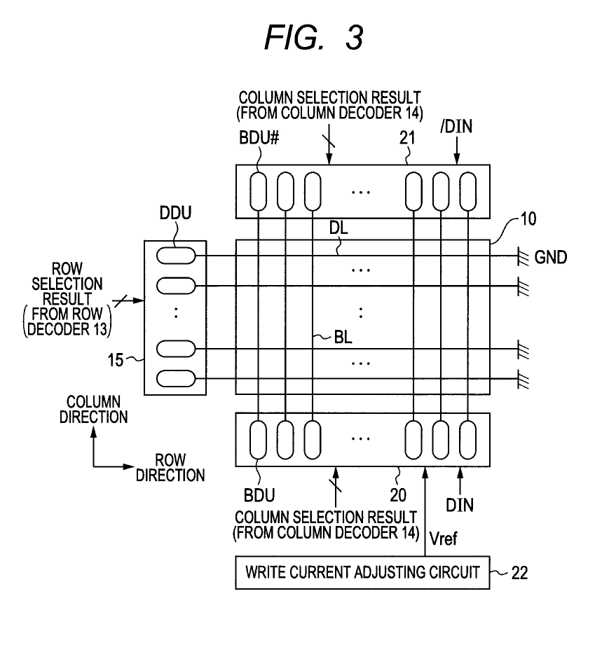

FIG. 3 is a block diagram illustrating arrangement of signal wiring used for a data write in the MTJ memory cell array 10.

As illustrated in FIG. 3, in the MTJ memory cell array 10, a digit line DL is arranged corresponding to each of rows of the normal memory cell (henceforth, also called a “memory cell row”). A bit line BL is arranged corresponding to each of columns of the normal memory cell (henceforth, also called a “memory cell column”). Although not shown, a word line WL and a source line SL are arranged corresponding to each of the memory cell rows.

The digit line drive circuit 15 has a digit line drive unit DDU for controlling voltage at one end of the digit line DL, corresponding to a column selection result from the row decoder 13. The other end (the opposite side of the digit line drive unit) of each digit line DL is coupled to the ground voltage GND fixedly, irrespective of the row selection result.

In the digit line drive circuit 15, the digit line drive unit DDU corresponding to a selected row couples one end of the corresponding digit line, namely, the digit line of the selected row, to a power supply voltage Vcc, for example. Accordingly, a predetermined write current is supplied to the digit line of the selected column in the direction which goes from the power supply voltage Vcc to the ground voltage GND. A magnetic field produced by the write current which flows through the digit line DL has a direction parallel to the magnetization hard axis (HA) in the normal memory cell MC.

On the other hand, in non-selected rows, each digit line drive unit DDU couples one end of the corresponding digit line to the ground voltage GND. Therefore, a write current like in the selected row is not supplied to a digit line of the non-selected rows.

The bit line drive circuit 20 includes a bit line drive unit BDU provided corresponding to one end of each bit line BL. The bit line drive circuit 21 includes a bit line drive unit BDU# provided corresponding to the other end of each bit line BL.

Each bit line drive unit BDU controls voltage at the one end of the corresponding bit line BL, corresponding to the column selection result and a level of the write data DIN, supplied from the column decoder 14. On the other hand, each bit line drive unit BDU# controls voltage at the other end of the corresponding bit line BL, corresponding to the column selection result and the inverted write data/DIN, supplied from the column decoder 14.

At the time of the data write, the one end and the other end of the bit line of the selected column are set to one of the power supply voltage Vcc and the ground voltage GND, corresponding to the level of the write data DIN. For example, when the write data DIN is at an H level, the one end of the bit line of the selected column is coupled to the power supply voltage Vcc by the corresponding bit line drive unit BDU, and the other end of the bit line of the selected column is coupled to the ground voltage GND by the corresponding bit line drive unit BDU#. On the contrary, when the write data DIN is at an L level, the one end of the bit line of the selected column is coupled to the ground voltage GND by the corresponding bit line drive unit BDU, and the other end of the bit line of the selected column is coupled to the power supply voltage Vcc by the corresponding bit line drive unit BDU#.

On the other hand, in a non-selected column, one end and the other end of a bit line BL are coupled to the ground voltage GND by the corresponding bit line drive units BDU and BDU#, respectively. Therefore, a write current does not flow through the bit line of the non-selected column.

At the time of a data read, each of the bit line drive units BDU and BDU# separates the one end and the other end of a bit line BL from both of the power supply voltage Vcc and the ground voltage GND. At the time of the data read, a data read current is supplied to a bit line BL electrically coupled to the selected memory cell, by a data read circuit (not shown).

In FIGS. 1 to 3, although only the circuits relevant to the data write are illustrated typically, a data read circuit (not shown) for realizing the data read operation to the MTJ memory cell MC is assumed to be further provided. Such a data read circuit has, for example, a function to supply a data read current to a bit line BL at the time of a data read, and a function to detect a bit-line (BL) flowing current which is dependent on the electric resistance of the selected memory cell.

Referring to FIG. 1 again, in the configuration according to the embodiments of the present invention, in a peripheral area of the MTJ memory cell array 10, a dummy cell DC is further provided so as to continue the arrangement pattern of the normal memory cell MC. That is, the normal memory cell MC and the dummy cell DC are continuously arranged so that a uniform pitch may be preserved as a whole. Although the dummy cell DC is designed in the same structure and size as the normal memory cell MC, it is not necessary to design both in the same structure completely.

FIG. 1 illustrates a configuration in which three rows of dummy cells DC along the row direction and two columns of dummy cells DC along the column direction are arranged. However, the number of dummy cells DC in the arrangement is not limited in particular.

As illustrated in FIG. 1, by arranging dummy cells DC in the peripheral area of the MTJ memory cell array 10, it is possible to reduce the nonuniformity of size, shape, and structure which may be produced at the time of manufacture of the MTJ memory cell, due to roughness and fineness of the MTJ memory cell arrangement. Since an MTJ memory cell is formed only in a portion of the MTJ memory array in the MRM circuit block, roughness and fineness of the arrangement of the MTJ memory cell will be generated in a chip. That is, in a center portion of the MTJ memory cell array, an MTJ memory cell is arranged continuously; accordingly, the density of arrangement is high. However, a peripheral portion of the MTJ memory cell array adjoins an area where an MTJ memory cell is not arranged; accordingly, the density of arrangement becomes low. When an area with a high density of arrangement of the MTJ memory cell and an area with a low density of arrangement are intermingled within the same chip, nonuniformity will be generated to some extent in size and shape of the MTJ memory cell between these areas. Such nonuniformity becomes conspicuous especially in the tunneling magnetoresistive element TMR which forms a part of the magnetic tunnel junction.

Accordingly, a dummy cell DC is arranged in an area where the density of arrangement of the MTJ memory cell is low, in order that an area where nonuniformity is generated in shape and size of the MTJ memory cell is confined within the arrangement area of the dummy cell DC. Consequently, it is possible to manufacture uniformly all the normal memory cells MC that configure the MTJ memory cell array 10. That is, between a normal memory cell MC located in the central part of the MTJ memory cell array 10 and a normal memory cell MC located in the boundary part of the MTJ memory cell array 10, the uniformity of size, shape, and structure, namely, the uniformity of a memory cell pattern, is maintained with respect to the strap layer SRP, the tunneling magnetoresistive element TMR, and the buffer layer. In this case, the size of the arrangement area of the dummy cell DC is adjusted to such an extent that the normal memory cell MC is formed in a uniform shape, as described above.

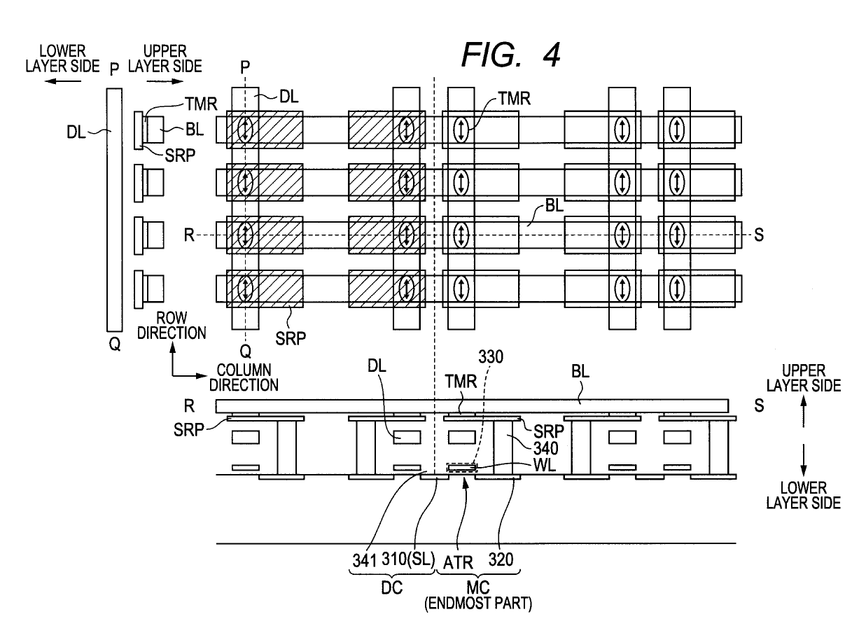

FIG. 4 illustrates detailed arrangement of normal memory cells, dummy cells, and corresponding signal lines.

The central part of FIG. 4 illustrates a plan view of MTJ memory cells MC and dummy cells DC arranged continuously in a matrix, and the corresponding wiring group. FIG. 4 illustrates typically the arrangement of MTJ memory cells MC in three rows by four columns and the arrangement of dummy cells DC in two rows by four columns.

As illustrated in the plan view, five digit lines DL respectively corresponding to five memory cell rows along the row direction and four bit lines BL respectively corresponding to four memory cell columns along the column direction are arranged. Although not illustrated, a source line SL is also arranged along the row direction.

A tunneling magnetoresistive element TMR is arranged at each of intersections of the bit line BL and the digit line DL. An access transistor ATR is formed on the lower layer side of the tunneling magnetoresistive element TMR.

FIG. 4 further illustrates a P-Q sectional view and an R-S sectional view on the plan view. As illustrated in the R-S sectional view, an active layer which forms a source/drain region 310 of the access transistor ATR is provided, extending in the row direction so that it is shared by the access transistors ATR corresponding to the same row. That is, this active layer is coupled to the ground voltage GND and acts as a source line SL.

A source/drain region 320 is electrically coupled to the strap SRP via a contact hole 340. In a gate region 330 of the access transistor ATR, a word line WL is arranged, extending in the row direction. In a middle layer between the word line WL and the strap SRP, the digit line DL is arranged, extending in the row direction.

The P-Q sectional view in FIG. 4 illustrates a sectional view corresponding to the digit line DL. In the P-Q sectional view, only the upper layer side than the digit line DL is illustrated.

Since the digit line DL flows a write current for writing data in a tunneling magnetoresistive element TMR, the digit line DL is arranged in an area directly under the tunneling magnetoresistive element TMR. Therefore, in the upper layer of the digit line DL, the tunneling magnetoresistive element TMR electrically coupled to the strap SRP and the bit line BL is arranged.

For example, dummy cells DC can be secured by arranging more MTJ memory cells than the necessary number of memory cells as accessing targets, continuously in a uniform pitch. In the present case, a group of surplus MTJ memory cells located in the peripheral area are manufactured as the dummy cells DC. In the case, each of the normal memory cells MC and the dummy cells DC have completely same structure, and dummies are secured for each of the tunneling magnetoresistive element TMR, the access transistor ATR, the bit line BL, the digit line DL, the word line WL, and the source line SL.

(Tuning of a write current) At the time of a data write, a write current is flowed in each of the digit line DL and the bit line BL. A value of the write current is tuned up to an appropriate value so that a write margin may be secured in order to accommodate variations of the magnetic properties of an MTJ memory cell due to a manufacturing variation. The following explains a tuning test of a write current to a general MTJ memory cell array.

Referring to FIG. 3 again, a write current adjusting circuit 22 for adjusting a write current IBL for the bit line BL is provided, corresponding to the bit line drive circuit 20. The write current adjusting circuit 22 outputs a reference voltage Vref for adjusting the current amount of the write current IBL.

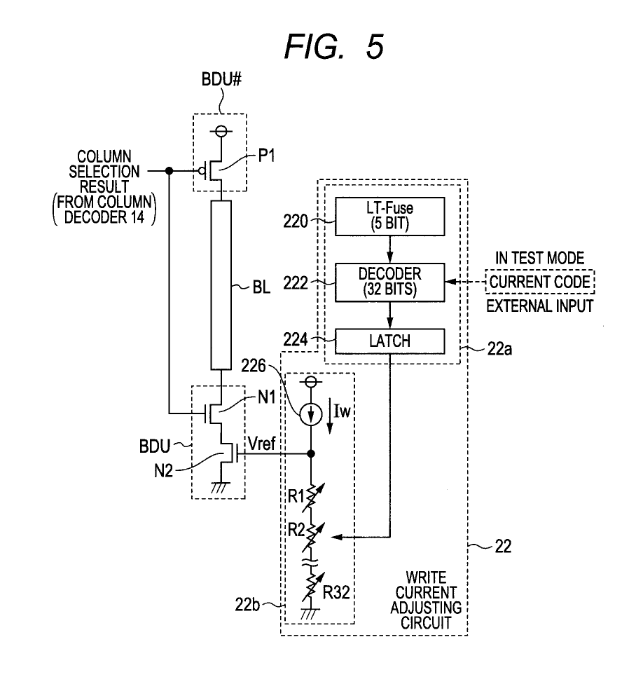

FIG. 5 is a circuit diagram illustrating a configuration of the write current adjusting circuit 22 illustrated in FIG. 3. The write current adjusting circuit 22 illustrated in FIG. 5 is applicable both to a write current adjusting circuit for adjusting a write current IDL for the digit line DL and to a write current adjusting circuit for adjusting a write current IBL for the bit line BL.

As illustrated in FIG. 5, the bit line drive unit BDU# includes a P-channel MOS transistor P1 which receives at the gate thereof an input of a column selection result from the column decoder 14.

The bit line drive unit BDU includes an N-channel MOS transistor N1 which receives at the gate thereof an input of the column selection result from the column decoder 14, and an N-channel MOS transistor N2 which receives at the gate thereof an input of the reference voltage Vref. The P-channel MOS transistor P1 and the N-channel MOS transistor N1 are arranged corresponding to the bit line BL, and configure “transistors for column selection.” The P-channel MOS transistor P1 and the N-channel MOS transistor N1 are set in an on state based on the column selection result outputted by the column decoder 14.

The write current adjusting circuit 22 generates the reference voltage Vref at the time of executing a tuning test of a write current (henceforth, also called a test mode) and at the time of a normal operation (henceforth, also called a normal mode), respectively. Specifically, the write current adjusting circuit 22 includes a tuning input unit 22a and a voltage adjusting unit 22b which adjusts the reference voltage Vref corresponding to a setup to the tuning input unit 22a.

The tuning input unit 22a includes a fuse circuit 220 for programming an appropriate value (current code) obtained by the tuning test to be described later, a decoder 222 which decodes the current code stored in the fuse circuit 220, and a latch 224 which latches the decoded current code.

The fuse circuit 220 includes a fuse element serving as a program element. The fuse can be blown by entering a laser light into the fuse element from the exterior directly, or by inputting a high voltage signal from the exterior via a blow input node. Corresponding to whether a fuse element has been blown or not, a current code (for example, coded in 5 bits) which specifies the appropriate amount of a write current is programmed in a nonvolatile manner.

The decoder 222 includes an input terminal which receives a current code programmed by the fuse circuit 220 in the normal mode, and an input terminal which receives a current code inputted from the exterior in the test mode. The decoder 222 decodes a 5-bit current code into a value of 32 bits, in each of the normal mode and the test mode. The latch 224 latches the decoded result output by the decoder 222.

The voltage adjusting unit 22b includes a constant current source 226 and 32 variable resistive elements R1 to R32, coupled in series between the power supply voltage Vcc and the ground voltage Vss. A connection node of the constant current source 226 and the variable resistive element R1 is coupled to a gate of the N-channel MOS transistor N2 in the bit line drive unit BDU. The constant current source 226 supplies a constant current Iw.

The voltage level of the reference voltage Vref generated at the connection node is controlled, by controlling each value of resistance of the variable resistive elements R1 to R32 corresponding to the 32-bit current code outputted from the latch 224. That is, the reference voltage Vref is determined by product of the value of resistance of the variable resistive elements R1 to R32, and the current Iw. The value of resistance of the variable resistive elements R1 to R32 changes in 32 steps corresponding to the current code supplied from the tuning input unit 22a. Therefore, in the test mode, the reference voltage Vref can be changed in 32 steps by changing the value of resistance of the variable resistive elements R1 to R32 in 32 steps by changing the current code inputted from the exterior between 0 and 31.

When the N-channel MOS transistor N2 is set in an on state upon receiving the reference voltage Vref at the gate, the current amount of the write current IBL, which flows through the bit line BL corresponding to the column selection transistors P1 and N1 set in an on state, is adjusted in 32 steps. That is, the N-channel MOS transistor N2 configures a “current adjusting transistor.”

Therefore, in the test mode, it is possible to easily perform a tuning test of the current amount of a write current for securing an appropriate write margin by adjusting the current amount reversibly, without actually performing a fuse blow.

After the end of the tuning test, it is possible to program a current code for obtaining an appropriate write current in a nonvolatile manner in the tuning input unit 22a, by blowing a fuse element based on the test result. As a result, since the write current adjusting circuit 22 generates the appropriate reference voltage Vref according to the programmed current code in the normal mode, it becomes possible to perform a data write operation in the normal operation, with the compensation for a manufacturing variation in the magnetic properties of the MTJ memory cell.

In the above configuration, in the test mode, arbitrary current codes are inputted from the exterior and a memory performance test is performed. The memory performance test is performed as follows: usually a write current is gradually changed within the predetermined limits of the current value by changing the current code one by one between 0 and 31, and it is checked whether a data write is normally performed in all the MTJ memory cells of the MTJ memory cell array which is integrally arranged in the MRAM circuit block mounted in a system LSI.

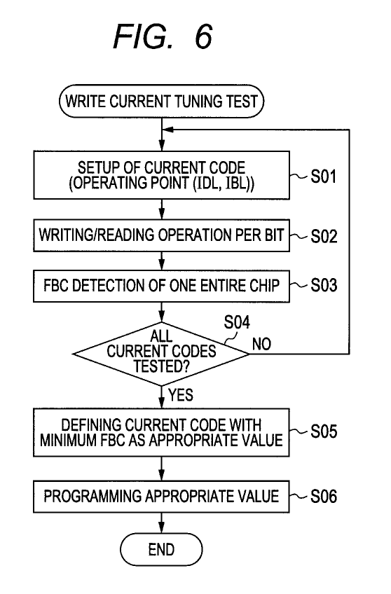

FIG. 6 is a flowchart explaining the tuning test of a write current. As illustrated in FIG. 6, by inputting a current code into the tuning input unit 22a from the exterior, an operating point at the time of a data write is set up (Step S01). This current code expresses write current IBL for the bit line BL, and a write current IDL for the digit line DL. Accordingly, the operating point of the MTJ memory cell is set up.

Subsequently, a memory performance test is conducted under the condition of the operating point set up at Step S01 (Step S02). Specifically, one MTJ memory cell MC as a write target is selected from the MTJ memory cell array 10, and data for the test is written in to the MTJ memory cell MC as the write target. Subsequently, a data read is performed to all the MTJ memory cells MC included in the MTJ memory cell array 10. Then, it is checked that the data write has been performed normally, namely, that the data for the test can be read out from the MTJ memory cell MC as the write target, and that data stored in an MTJ memory cell MC which is not the write target is not rewritten accidentally.

The above check is performed for a case where all the MTJ memory cells MC included in the MTJ memory cell array 10 are respectively set as a memory cell of the write target. Specifically, the number of fail bits FBC is detected by counting a fail bit by a fail bit counter (Step S03).

Subsequently, it is determined whether the memory performance test has been conducted for all values that the current code can take (Step S04). When the memory performance test has not yet been conducted for all values that the current code can take (NO at Step S04), the present current code is incremented by one and the memory performance test is conducted again.

On the other hand, when the memory performance test has been completed for all values that the current code can take (YES at Step S04), a current code when the number of fail bits FBC exhibits a minimum value is selected. The write current IBL specified by the selected current code is set as an appropriate value of the write current (Step S05). The appropriate value of the write current (current code) is programmed into the fuse circuit 220 illustrated in FIG. 5 (Step S06).

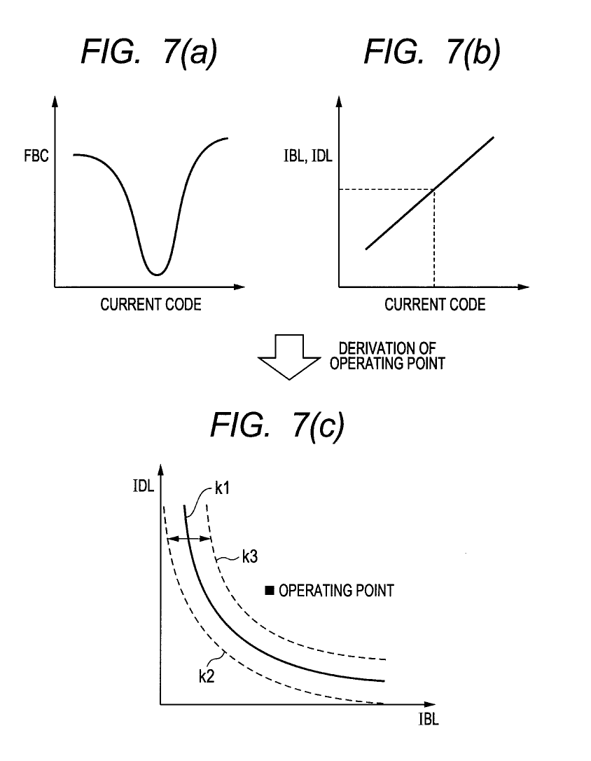

FIG. 7A, FIG. 7B, and FIG. 7C are conceptual diagrams illustrating the tuning test result of write current. FIG. 7A illustrates a detection result of the number of fail bits (FBC) versus the current code, which is obtained by conducting the memory performance test for all the values that the current code can take. When a current code corresponding to the minimum of FBC is obtained from the present detection result, the write currents IDL and IBL corresponding to the obtained current code is calculated, based on a relation of the current code and the write currents IDL and IBL as illustrated in FIG. 7B. The calculated write currents IDL and IBL are defined as an appropriate write current to all the MTJ memory cells included in the MTJ memory cell array.

FIG. 7C is a drawing illustrating an astroid curve of an MTJ memory cell. As shown in FIG. 7C, the astroid curve (a solid line k1 in the figure) expresses a threshold of a write current IBL and a write current IDL. That is, in an area below the astroid curve, since the write current IBL and the write current IDL are not large enough to exceed the threshold, a write to the MTJ memory cell is not performed. In an area above the astroid curve, since the write current IBL and the write current IDL exceed the threshold, a write to the MTJ memory cell is performed. Therefore, the area above the astroid curve is an effective area as a write current to the MTJ memory cell, and an operating point of the MTJ memory cell at the time of a data write is set up so that the write currents IBL and IDL are included in the present area. Generally, the write currents IBL and IDL are set as the current amount of the current threshold added with a margin.

Here, in FIG. 7C, dashed lines k2 and k3 express an astroid curve of MTJ memory cells different from the MTJ memory cell corresponding to the solid line k1. Although these MTJ memory cells are arranged in the same MTJ memory cell array, the threshold of a write current varies due to a manufacturing variation, etc. Therefore, in order to perform a data write normally to all the MTJ memory cells included in the MTJ memory cell array 10, it is necessary, as illustrated in FIG. 7C, to set the operating point for a data write in an area above the astroid curve k3 for the MTJ memory cell with the highest current threshold. That is, the current amount of a write current will be tuned up on the basis of an MTJ memory cell with the highest threshold of a write current in the MTJ memory cell array.

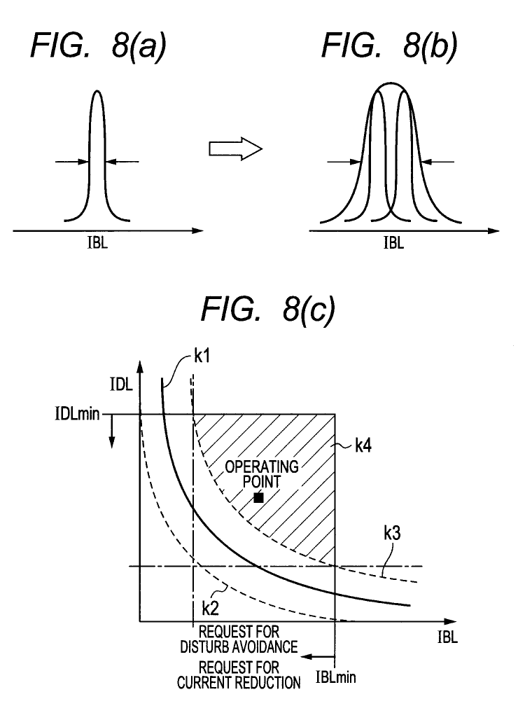

However, when the number of MTJ memory cells arranged in an MTJ memory cell array increases in connection with an MRAM circuit block increasing in capacity, the degree of variation of a threshold of the write current will become large. FIG. 8A illustrates variations in the write current IBL among plural MTJ memory cells coupled to one bit line BL, and FIG. 8B illustrates variations in the write current IBL in the entire MTJ memory cell array. As clearly seen from the comparison of both figures, even if the degree of variation of the write current IBL for one bit line BL is small, the degree of variation increases when the MTJ memory cell array is integrated into one chip as an MRAM circuit block.

Accordingly, as illustrated in FIG. 8C, in an MTJ memory cell array, an astroid curve of each MTJ memory cell will be distributed between the dashed line k2 and the dashed line k3. In order to perform a data write to all the MTJ memory cells, the write currents IDL and IBL need to be set outside the dashed line k3 at least.

Here, the write currents IDL and IBL also affect MTJ memory cells other than the target MTJ memory cell (occurrence of disturb). In order to write data in an MTJ memory cell of the write target selectively, it is necessary that a write to an MTJ memory cell which is not the target is not performed, by either of the write currents IDL and IBL. Therefore, the write current IDL needs to be smaller than IDLmin, and the write current IBL needs to be smaller than IBLmin. Accordingly, it is necessary that the write currents IDL and IBL are set within a hatched area k4 (a write margin, a selected write area) in FIG. 8C. However, the write margin becomes small as a variation in the magnetic properties of an MTJ memory cell becomes large.

When the write currents IDL and IBL become large, an occupied area of a peripheral circuit necessary for control of the write currents will become large, acting as a hindrance to large integration of MTJ memory cells, and furthermore causing increase of power consumption of the MRAM circuit block.

As described above, when adopting a configuration in which a write current is adjusted to a single appropriate value to all the MTJ memory cells included in the MTJ memory cell array, a write margin becomes reduced due to variations in the magnetic properties of the MTJ memory cells. Also, increase of the write current for compensating the variations in the magnetic properties of the MTJ memory cells causes increase of power consumption of the MRAM circuit block.

Furthermore, in order to compensate the degree of variations of the magnetic properties of the MTJ memory cells, it is necessary to prepare many current codes and many fuse circuits for programming the current codes. Accordingly, there arises a problem that an occupied area of the MRAM circuit block becomes large.

The following explains a tuning operation of a write current according to the embodiment of the present invention, with reference to the drawings. The tuning operation of a write current explained in the following is applied to an MRAM device as a typical example of a nonvolatile memory device according to the embodiment of the present invention illustrated in FIG. 1.

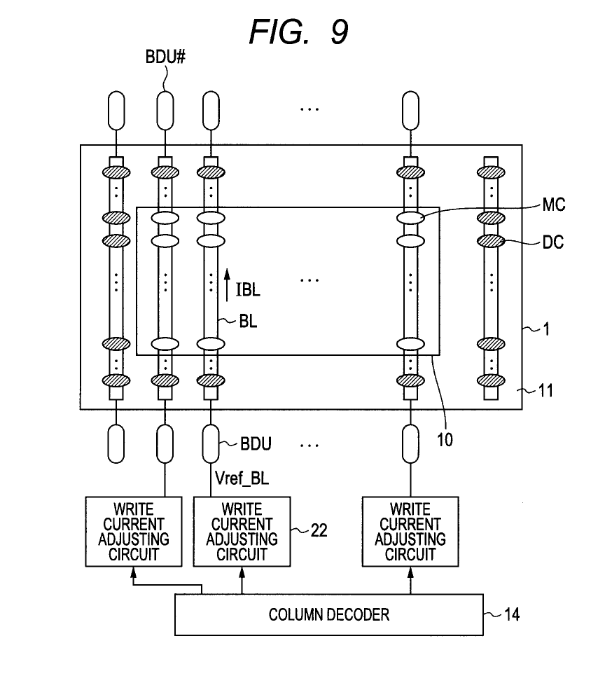

(Tuning of a write current according to Embodiment 1) FIG. 9 is a schematic diagram illustrating a tuning operation of write current according to Embodiment 1 of the present invention. As illustrated in FIG. 1, the MRAM device according to Embodiment 1 includes the MTJ memory cell array 10 in which MTJ memory cells (normal memory cells) MC are arranged in a matrix, and dummy cells DC are provided in the peripheral area of the MTJ memory cell array 10, so as to continue the arrangement pattern of the normal memory cells MC.

In Embodiment 1, plural bit lines BL provided corresponding to each memory cell column are divided in units of at least one column, and the current amount of a write current IBL is adjusted for every division unit. FIG. 9 illustrates an example of the case in which the plural bit lines BL are divided in units of one column, and the write current adjusting circuit 22 is provided for every division unit.

In FIG. 9, a write current adjusting circuit 22 is coupled between a bit line drive unit BDU and the column decoder 14. The write current adjusting circuit 22 adjusts a write current IBL which flows through a bit line BL corresponding to a selected column, according to the column selection result from the column decoder 14. Specifically, the write current adjusting circuit 22 includes the tuning input unit 22a and the voltage adjusting unit 22b which adjusts the reference voltage Vref corresponding to a setup to the tuning input unit 22a, as explained in FIG. 5. The write current adjusting circuit 22 generates the reference voltage Vref and outputs it to the corresponding bit line drive unit BDU, in each of the test mode and the normal mode. In the test mode, the reference voltage Vref is adjusted by inputting arbitrary current codes from the exterior and conducting the memory performance test according to the flow chart illustrated in FIG. 7.

In the memory performance test, it is checked whether a data write is performed normally in all the MTJ memory cells MC coupled to the bit line BL of the selected column. Specifically, setting all the MTJ memory cells MC coupled to the bit line BL of the selected column, as a write target one by one, a write of test data and a read of the data are performed and it is checked that the data write is performed normally. When it is checked that the data write has been normally performed to all the MTJ memory cells MC, the current amount corresponding to the current code at the time is set as an appropriate value of the write current IBL.

In this way, by adopting a configuration in which plural bit lines BL are divided in units of at least one column, and adjusting the current amount of the write current IBL for every division unit, the degree of variations of the magnetic properties of an MTJ memory cell included in the division units becomes small, as compared with a configuration in which the current amount of a write current is adjusted in the entire MTJ memory cell array. As a result, it is possible to expand a write margin in the division units and to secure a sufficient write margin.

FIG. 9 illustrates the configuration in which plural bit lines BL are divided in units of one bit line BL, and the write current IBL is adjusted for every division unit. However, the division may be made in units of plural bit lines BL and the write current IBL may be adjusted. Alternatively, the MTJ memory cell array 10 may be divided into plural memory mats, and a write current IBL may be adjusted in units of a memory mat.

### Modified Example 1

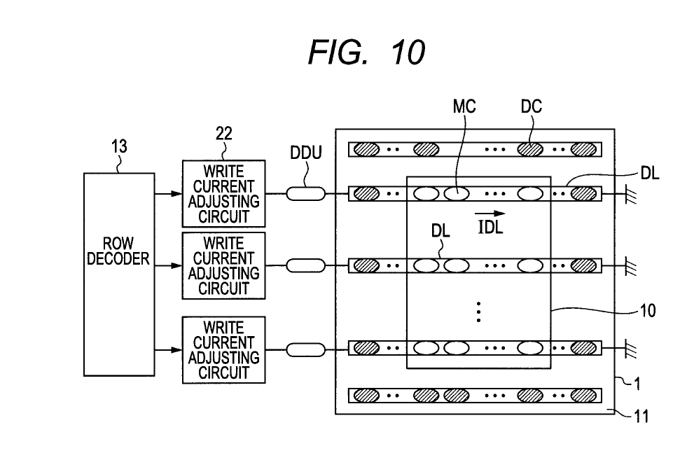

FIG. 10 is a schematic diagram illustrating a tuning operation of write current according to Modified Example 1 of Embodiment 1 of the present invention.

As illustrated in FIG. 10, in Modified Example 1, plural digit lines DL provided corresponding to each memory cell row are divided in units of at least one row, and the current amount of a write current IDL is adjusted for every division unit. FIG. 10 illustrates an example of the case in which plural digit lines DL are divided in units of one row and a write current adjusting circuit 22 is provided for every division unit.

In FIG. 10, a write current adjusting circuit 22 is coupled between a digit line drive unit DDU and the row decoder 13. The write current adjusting circuit 22 adjusts a write current IDL which flows through a digit line DL corresponding to a selected row, according to the row selection result supplied by the row decoder 13. Specifically, the write current adjusting circuit 22 includes the tuning input unit 22a and the voltage adjusting unit 22b which adjusts the reference voltage Vref corresponding to a setup to the tuning input unit 22a, as explained in FIG. 5. In each of the test mode and the normal mode, the write current adjusting circuit 22 generates a reference voltage Vref, and outputs it to the corresponding digit line drive unit DDU. In the test mode, the reference voltage Vref is adjusted by inputting arbitrary current codes from the exterior and performing the memory performance test according to the flow chart illustrated in FIG. 7.

In the memory performance test, it is checked whether a data write is performed normally in all the MTJ memory cells coupled to the digit line DL of the selected row. Specifically, setting all the MTJ memory cells MC coupled to the digit line DL of the selected row, as a write target one by one, a write of test data and a read of the data are performed and it is checked that the data write is performed normally. When it is checked that the data write has been normally performed to all the MTJ memory cells MC, the current amount corresponding to the current code at the time is set as an appropriate value of the write current IDL.

In this way, by adopting a configuration in which plural digit lines DL are divided in units of at least one row, and adjusting the current amount of the write current IDL for every division unit, the degree of variations of the magnetic properties of an MTJ memory cell included in the division units becomes small, as compared with a configuration in which the current amount of a write current is adjusted in the entire MTJ memory cell array. As a result, it is possible to expand a write margin in the division units and to secure a sufficient write margin.

FIG. 10 illustrates the configuration in which plural digit lines DL are divided in units of one row, and the write current IDL is adjusted for every division unit. However, the division may be performed in units of plural digit lines DL and the write current IDL may be adjusted. Alternatively, the MTJ memory cell array 10 may be divided into plural memory mats, and a write current IDL may be adjusted in units of a memory mat.

### Modified Example 2

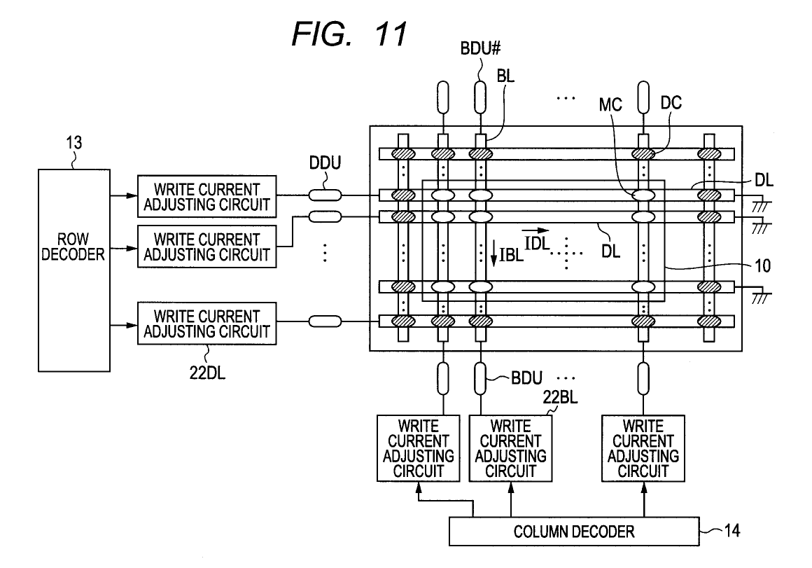

FIG. 11 is a schematic diagram illustrating an adjusting operation of write current according to Modified Example 2 of Embodiment 1 of the present invention.

As illustrated in FIG. 11, in Modified Example 2, plural bit lines BL provided corresponding to each memory cell column are divided in units of at least one column, and the current amount of a write current IBL is adjusted for every division unit, and plural digit lines DL provided corresponding to each memory cell row are divided in units of at least one row, and the current amount of a write current IDL is adjusted for every division unit. FIG. 11 illustrates an example of the case in which plural bit lines BL are divided in units of one column and a write current adjusting circuit 22BL is provided for every division unit, and the plural digit lines DL are divided in units of one row, and a write current adjusting circuit 22DL is provided for every division unit.

In FIG. 11, a write current adjusting circuit 22BL for adjusting the write current IBL is coupled between a bit line drive unit BDU and the column decoder 14. A write current adjusting circuit 22DL for adjusting the write current IDL is coupled between a digit line drive unit DDU and the row decoder 13. Each of the write current adjusting circuits 22BL and 22DL has the same configuration as the write current adjusting circuit 22 explained in FIG. 5.

By adopting such a configuration, the current amount of the write currents IBL and IDL is adjusted in the respective division units. Accordingly, it is possible to attain minute tuning of the write currents IBL and IDL and to improve the write margin further.

### Embodiment 2

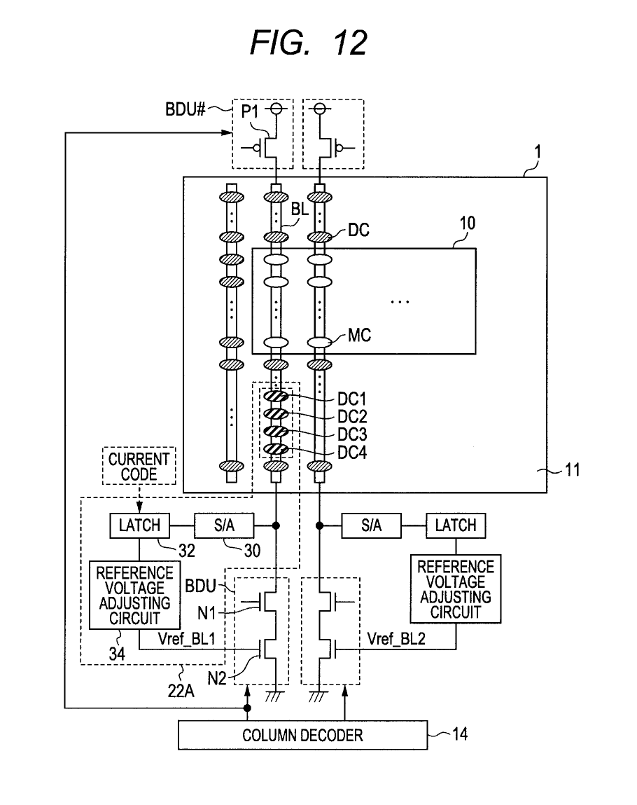

FIG. 12 is a schematic diagram illustrating an adjusting operation of write current according to Embodiment 2 of the present invention. As illustrated in FIG. 1, the MRAM device according to Embodiment 2 includes the MTJ memory cell array 10 in which MTJ memory cells (normal memory cells) MC are arranged in a matrix, and dummy cells DC are provided in the peripheral area of the MTJ memory cell array 10, so as to continue the arrangement pattern of the normal memory cells MC.

In Embodiment 2, plural bit lines BL provided corresponding to each memory cell column are divided in units of at least one column, and the current amount of a write current IBL is adjusted for every division unit. FIG. 12 illustrates an example of the case in which plural bit lines BL are divided in units of one column and a write current adjusting circuit 22A is provided for every division unit.

The write current adjusting circuit 22A generates a reference voltage Vref_BL and outputs it to the corresponding bit line drive unit BDU, in each of the test mode and the normal mode. The current adjusting circuit 22A includes a sense amplifier (S/A) 30, a latch circuit 32, a reference voltage adjusting circuit 34, and dummy cells DC1 to DC4. Among these, the dummy cells DC1 to DC4, the sense amplifier 30, and the latch circuit 32 configure a “tuning input unit” for inputting a setting value (current code) of the write current IBL, and the reference voltage adjusting circuit 34 configures a “voltage adjusting unit” which adjusts the reference voltage Vref_BL on a bit line by bit line basis, according to the current code supplied from the tuning input unit.

The write current adjusting circuit 22A according to Embodiment 2 is different from the write current adjusting circuit 22 illustrated in FIG. 5 in the point that the tuning input unit includes the dummy cells DC1 to DC4 instead of the fuse circuit 220. The dummy cells DC1 to DC4 function as a program element which stores, in a nonvolatile manner, a current code obtained by the tuning test of a write current IBL performed in units of bit lines.

The dummy cell DC is designed fundamentally in the same structure as the normal memory cell MC (especially in the portion of the tunneling magnetoresistive element TMR), in order to maintain the uniformity of all the normal memory cells MC which configure the MTJ memory cell array 10, as explained in FIG. 4. In Embodiment 2, the dummy cell DC stores a current code in a nonvolatile manner, instead of the fuse circuit.

Specifically, according to the current code as a tuning test result, each of the dummy cells DC1 to DC4 is set to an on state or to an off state. For example, a dummy cell DC is set to an on state, by destroying electrically with the application of a high voltage (voltage stress) exceeding a maximum rating to the dummy cell DC. On the other hand, a dummy cell DC to which a high voltage is not applied is set to an off state. In FIG. 12, four dummy cells DC1 to DC4 function as a program element corresponding to a 4-bit current code. However, the number of dummy cells DC utilized as a program element can be changed according to the number of bits of the current code.

The sense amplifier 30 is included in the data read circuit for practicing a data read operation to an MTJ memory cell MC, and is arranged corresponding to each memory cell column. At the time of a data read, the sense amplifier 30 detects a data read current which flows through a bit line BL and a source line SL, and outputs read data generated on the basis of the detection result, to the exterior via an interface circuitry.

At the time of a data write, the sense amplifier 30 reads a current code stored in the dummy cells DC1 to DC4. The latch circuit 32 latches the read current code.

The reference voltage adjusting circuit 34 generates the reference voltage Vref_BL based on the current code outputted by the latch circuit 32, and applies the generated reference voltage Vref_BL to a gate of the N-channel MOS transistor N2 which is a current adjusting transistor in the bit line drive unit BDU.

FIG. 13 is a circuit diagram illustrating a configuration of the reference voltage adjusting circuit 34 illustrated in FIG. 12. As illustrated in FIG. 13, the reference voltage adjusting circuit 34 includes a constant current source 342, resistors R1 to R4 which are coupled in series between the constant current source 342 and the ground voltage, N-channel MOS transistors Tr1 to Tr4 which are respectively coupled in parallel to the resistors R1 to R4, and a drive circuit 340 which drives each gate of the N-channel MOS transistors Tr1 to Tr4.

Upon receiving the current code from the latch circuit 32, the gate driving circuit 340 drives each gate of the N-channel MOS transistors Tr1 to Tr4 to an H level or an L level according to the current code concerned. At this time, each N-channel MOS transistor shifts from an off state to an on state, when the gate is driven to an H level. Accordingly, the constant current Iw inputted from the constant current source 342 flows through this N-channel MOS transistor. In this way, the value of resistance of the current path which goes from the constant current source 342 to the ground voltage can be set variably, by the gate driving circuit 340 driving each N-channel MOS transistor to an on state or an off state according to the current code. Consequently, a voltage corresponding to a product of the value of resistance and the constant current Iw is applied to the gate of the N-channel MOS transistor N2, as the reference voltage Vref_BL. As a result, the write current IBL corresponding to the current code programmed to the dummy cells DC1 to DC4 flows through the bit line BL.

### Modified Example 1

Embodiment 2 has demonstrated in the above a case where the dummy cell DC is destroyed electrically by the application of a high voltage, thereby storing the current code. However, it is also possible to make the dummy cell DC store the current code with the use of a TMR effect which the dummy cell DC possesses.

Specifically, the electric resistance of a tunneling magnetoresistive element TMR becomes in a high resistance state or a low resistance state, when the relative relation of a magnetization direction between a fixed magnetic layer and a free magnetic layer in the tunneling magnetoresistive element TMR included in each dummy cell DC is changed, according to the level (“1” and “0”) of the current code. The high resistance state is associated with a logical level “1” of the current code, and the low resistance state is associated with a logical level “0” of the current code.

According to Modified Example 1, by adopting such a configuration, it is possible to make the dummy cell DC store a current code by performing the same processing as a data write to the normal memory cell MC. Accordingly, processing for applying a high voltage to a dummy cell DC becomes unnecessary, and the tuning operation of the write current is simplified.

### Modified Example 2

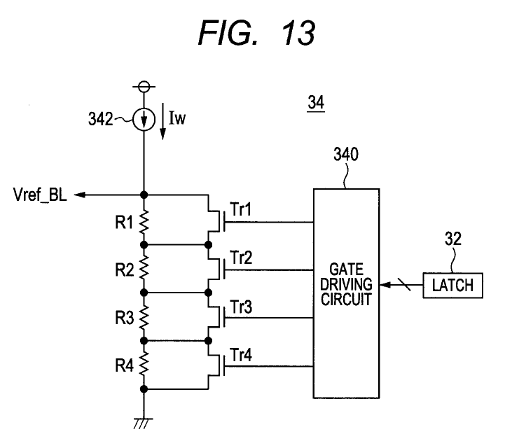

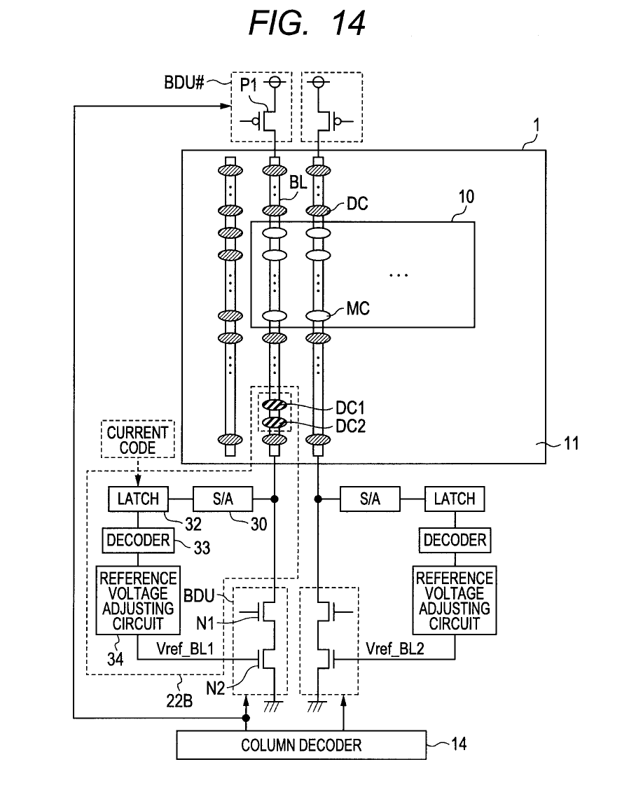

FIG. 14 is a schematic diagram illustrating a tuning operation of write current according to Modified Example 2 of Embodiment 2 of the present invention. As illustrated in FIG. 1, the MRAM device according to Modified Example 2 of Embodiment 2 includes the MTJ memory cell array 10 in which MTJ memory cells (normal memory cells) MC are arranged in a matrix, and dummy cells DC are provided in the peripheral area of the MTJ memory cell array 10, so as to continue the arrangement pattern of the normal memory cells MC.

In Modified Example 2, plural bit lines BL provided corresponding to each memory cell column is divided in units of at least one column, and the current amount of a write current IBL is adjusted for every division unit. FIG. 14 illustrates an example of the case in which plural bit lines BL are divided in units of one column and a write current adjusting circuit 22B is provided for every division unit. The write current adjusting circuit 22B generates the reference voltage Vref_BL and outputs it to the corresponding bit line drive unit BDU, in each of the test mode and the normal mode.

The write current adjusting circuit 22B according to Modified Example 2 is different from the write current adjusting circuit 22A illustrated in FIG. 12 in the point that the write current adjusting circuit 22B includes two dummy cells DC1 and DC2 as a program circuit and also includes a decoder 33 which decodes a current code latched to the latch circuit 32.

Each of the dummy cells DC1 and DC2 is made to store a current code using the TMR effect. Specifically, the electric resistance of the tunneling magnetoresistive element TMR becomes high resistance or low resistance, when the relative relation of a magnetization direction between a fixed magnetic layer and a free magnetic layer in the tunneling magnetoresistive element TMR included in each dummy cell DC is changed, according to the level (“1” and “0”) of the current code. By setting the electric resistance of the tunneling magnetoresistive element TMR of each dummy cell DC to high resistance or low resistance, it is possible to realize four combinations of (high resistance and high resistance), (high resistance and low resistance), (low resistance and high resistance), and (low resistance and low resistance), by the dummy cells DC1 and DC2 as a whole.

When the dummy cells DC1 and DC2 are set to (low resistance and low resistance), the reference voltage adjusting circuit 34 drives the gates of the N-channel MOS transistors Tr1 to Tr4 to an H level. Accordingly, the N-channel MOS transistors Tr1 to Tr4 shift from an off state to an on state altogether. As a result, the value of resistance of the current path which goes from the constant current source 342 to the ground voltage is set as the minimum.

On the other hand, when the dummy cells DC1 and DC2 are set to (high resistance and low resistance), the reference voltage adjusting circuit 34 drives the gates of the N-channel MOS transistors Tr1 to Tr3 to an H level, and drives the gate of the N-channel MOS transistor Tr4 to an L level. Accordingly, the N-channel MOS transistors Tr1 to Tr3 are set to an on state, and the N-channel MOS transistor Tr4 is set to an off state.

When the dummy cells DC1 and DC2 are set to (low resistance and high resistance), the reference voltage adjusting circuit 34 drives the gates of the N-channel MOS transistors Tr1 and Tr2 to an H level and drives the gates of the N-channel MOS transistors Tr3 and Tr4 to an L level. Accordingly, the N-channel MOS transistors Tr1 and Tr2 are set to an on state and the N-channel MOS transistors Tr3 and Tr4 are set to an off state.

Furthermore, when the dummy cells DC1 and DC2 are set to (high resistance and high resistance), the reference voltage adjusting circuit 34 drives the gate of the N-channel MOS transistor Tr1 to an H level and drives the gates of the N-channel MOS transistors Tr2 to Tr4 to an L level. Accordingly, the N-channel MOS transistor Tr1 is set to an on state, and the N-channel MOS transistors Tr2 to Tr4 are set to an off state.

By storing the setting value of the write current IBL adjusted per bit line to the dummy cells DC which are arranged in order to secure the uniformity of the MTJ memory cells as described above, it is possible to suppress the occupied area of the peripheral circuit to increase due to having provided a write current adjusting circuit per bit line. As a result, it becomes possible to secure the write margin, without increasing the occupied area of the MRAM circuit block.

### Embodiment 3

In Embodiment 2, the configuration in which the setting value of the write current IBL adjusted per bit line is stored in the dummy cells DC is explained. However, it is also possible to adopt a configuration in which the setting value of the write current IDL adjusted per digit line is stored in the dummy cells DC.

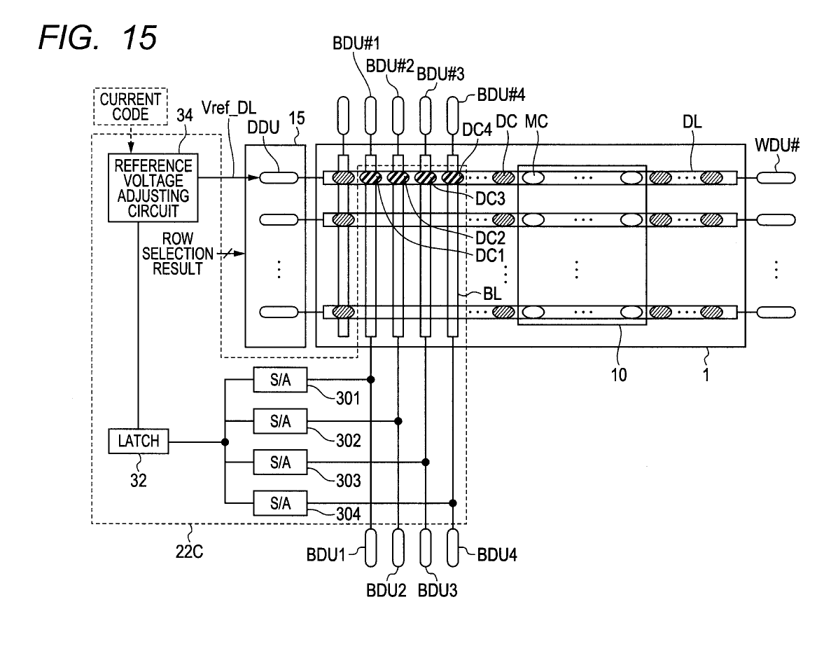

FIG. 15 is a schematic diagram illustrating a tuning operation of write current according to Embodiment 3 of the present invention. As illustrated in FIG. 1, the MRAM device according to Embodiment 3 includes the MTJ memory cell array 10 in which MTJ memory cells (normal memory cells) MC are arranged in a matrix, and dummy cells DC are provided in the peripheral area of the MTJ memory cell array 10, so as to continue the arrangement pattern of the normal memory cells MC.

In Embodiment 3, plural digit lines DL provided corresponding to each memory cell row are divided in units of at least one row, and the current amount of a write current IDL is adjusted for every division unit. FIG. 15 illustrates an example of the case in which plural digit lines DL are divided in units of one row and a write current adjusting circuit 22C is provided for every division unit.

The write current adjusting circuit 22C generates the reference voltage Vref_DL and outputs it to the corresponding digit line drive unit DDU, in each of the test mode and the normal mode. The write current adjusting circuit 22C includes sense amplifiers (S/A) 301 to 304, a latch circuit 32, a reference voltage adjusting circuit 34, and dummy cells DC1 to DC4 coupled to the common digit line DL. Among these, the dummy cells DC1 to DC4, the sense amplifiers 301 to 304, and the latch circuit 32 configure a “tuning input unit”, and the reference voltage adjusting circuit 34 configures a “voltage adjusting unit” which adjusts the reference voltage Vref_DL on a digit line by digit line basis, according to the setup to the present tuning input unit.

As is the case with the write current adjusting circuit 22A illustrated in FIG. 12, the write current adjusting circuit 22C according to Embodiment 3 makes the dummy cells DC1 to DC4 function as a program element which stores, in a nonvolatile manner, the current code obtained by the tuning test of a write current IDL in units of digit lines.

Specifically, according to the current code, each of the dummy cells DC1 to DC4 is set to an on state or an off state. As an example, a dummy cell DC is set to an on state by destroying electrically with the application of a high voltage exceeding a maximum rating to the dummy cell DC. On the other hand, a dummy cell DC to which a high voltage is not applied is set to an off state. In FIG. 12, four dummy cells DC1 to DC4 function as a program element corresponding to a 4-bit current code. However, the number of dummy cells DC utilized as a program element changes according to the number of bits of the current code.

It is also possible to make the dummy cell DC store the current code with the use of a TMR effect which the dummy cell DC possesses. Specifically, the electric resistance of the tunneling magnetoresistive element TMR becomes high resistance or low resistance, when the relative relation of a magnetization direction between a fixed magnetic layer and a free magnetic layer in the tunneling magnetoresistive element TMR included in each dummy cell DC is changed, according to the level (“1” and “0”) of the current code. Accordingly, it is possible to store a 1-bit current code (“1” and “0”).

The sense amplifiers 301 to 304 are arranged corresponding to four bit lines BL to which the dummy cells DC1 to DC4 are coupled, respectively. At the time of a data read, the sense amplifiers 301 to 304 detect a data read current which flows through the corresponding bit line BL and the source line SL, and output read data generated on the basis of the detection result, to the exterior via an interface circuitry.

At the time of a data write, the sense amplifiers 301 to 304 read a current code stored in the dummy cells DC1 to DC4. The latch circuit 32 latches the read current code.

The reference voltage adjusting circuit 34 generates the reference voltage Vref_DL based on a current code stored in the latch circuit 32, and applies the generated reference voltage Vref_DL to the digit line drive unit DDU. As a result, the write current IDL corresponding to the current code programmed to the dummy cells DC1 to DC4 flows through the digit line DL.

### Modified Example

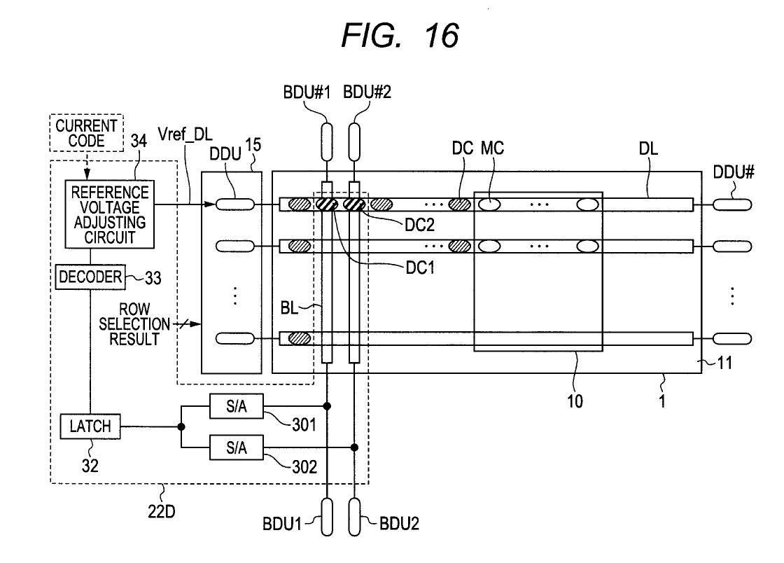

FIG. 16 is a schematic diagram illustrating a tuning operation of write current according to a modified example of Embodiment 3 of the present invention.

As illustrated in FIG. 16, in the present modified example, plural digit lines DL provided corresponding to each memory cell row are divided in units of at least one row, and the current amount of a write current IDL is adjusted for every division unit. FIG. 16 illustrates an example of the case in which plural digit lines DL are divided in units of one row and a write current adjusting circuit 22D is provided for every division unit. The write current adjusting circuit 22D generates the reference voltage Vref_DL and outputs it to the corresponding digit line drive unit DDU, in each of the test mode and the normal mode.

The write current adjusting circuit 22D according to the present modified example is different from the write current adjusting circuit 22C illustrated in FIG. 15 in the point that the write current adjusting circuit 22D includes two dummy cells DC1 and DC2 as a program circuit and also includes a decoder 33 which decodes a current code latched in the latch circuit 32.

Each of the dummy cells DC1 and DC2 is made to store a current code using the TMR effect. Specifically, the electric resistance of the tunneling magnetoresistive element TMR becomes high resistance or low resistance, when the relative relation of a magnetization direction between a fixed magnetic layer and a free magnetic layer in the tunneling magnetoresistive element TMR included in each dummy cell DC is changed, according to the level (“1” and “0”) of the current code. By setting the electric resistance of the tunneling magnetoresistive element TMR of each dummy cell DC to high resistance or low resistance, it is possible to realize four combinations of (high resistance and high resistance), (high resistance and low resistance), (low resistance and high resistance), and (low resistance and low resistance), by the dummy cells DC1 and DC2 as a whole. Relation between these four combinations and a value of resistance in the reference voltage adjusting circuit 34 is the same as what has been explained with reference to FIG. 14.

By storing the setting value of the write current IDL adjusted per digit line to the dummy cells DC which are arranged in order to secure the uniformity of the MTJ memory cell as described above, it is possible to suppress the occupied area of the peripheral circuit to increase due to having provided a write current adjusting circuit per digit line. As a result, it becomes possible to secure the write margin, without increasing the occupied area of the MRAM circuit block.

### Embodiment 4

In Embodiment 2, the configuration in which the setting value of the write current IBL adjusted per bit line is stored in the dummy cells DC is explained. However, it is also possible to utilize the present dummy cell DC as a transistor for adjustment of a write current IBL.

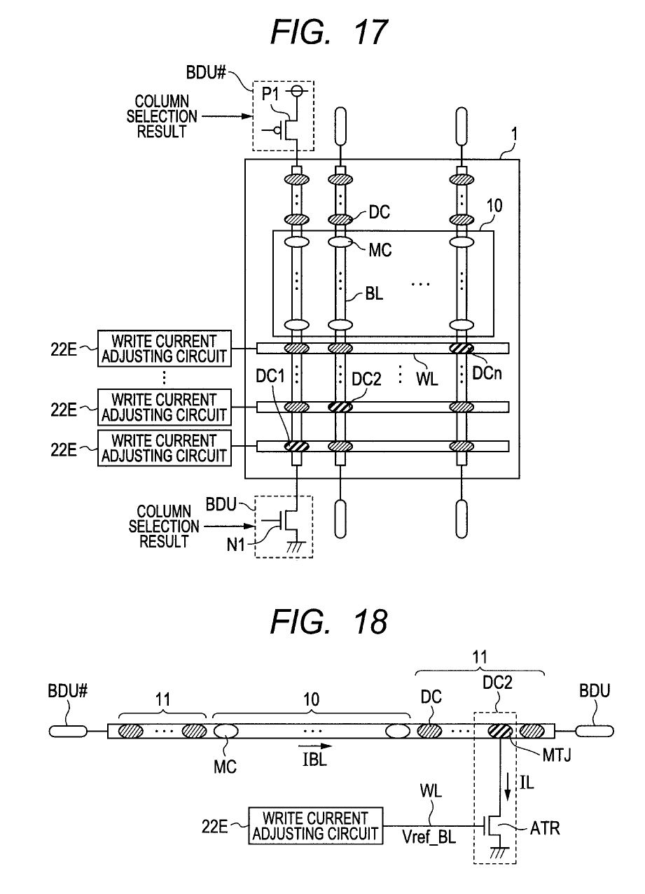

FIG. 17 is a schematic diagram illustrating a tuning operation of write current according to Embodiment 4 of the present invention. As illustrated in FIG. 1, the MRAM device according to Embodiment 4 includes the MTJ memory cell array 10 in which MTJ memory cells (normal memory cells) MC are arranged in a matrix, and dummy cells DC are provided in the peripheral area of the MTJ memory cell array 10, so as to continue the arrangement pattern of the normal memory cells MC.

In Embodiment 4, plural bit lines BL provided corresponding to each memory cell column are divided in units of at least one column, and the current amount of a write current IBL is adjusted for every division unit. FIG. 17 illustrates an example of the case in which plural bit lines BL are divided in units of one column and a write current adjusting circuit 22E is provided for every division unit.

The write current adjusting circuit 22E generates the reference voltage Vref_BL and outputs it to the corresponding bit line drive unit BDU, in each of the test mode and the normal mode. The write current adjusting circuit 22E includes a fuse circuit 220 and a reference voltage adjusting circuit 34. Among these, the fuse circuit 220 configures a “tuning input unit”, and the reference voltage adjusting circuit 34 configure a “voltage adjusting unit” which adjusts the reference voltage Vref_BL on a bit line by bit line basis, according to the setup to the present tuning input unit.

The reference voltage adjusting circuit 34 is coupled to a word line WL of the dummy cell DC, and outputs the generated reference voltage Vref_BL to the word line WL. In FIG. 17, the write current adjusting circuit 22E is provided to one dummy cell DC among the plural dummy cells DC coupled to a bit line BL. In FIG. 17, the dummy cells DC1 to DCn are selected respectively corresponding to n pieces of the bit lines BL (n is a natural number). These dummy cells DC1 to DCn are located in a different row among the bit lines BL. Corresponding to each of the dummy cells DC1 to DCn, a write current adjusting circuit 22E is provided.

FIG. 18 illustrates a configuration of one bit line BL among the plural bit lines BL illustrated in FIG. 17.

As illustrated in FIG. 18, normal memory cells MC and dummy cells DC are coupled to the bit line BL. The normal memory cells MC arranged in the MTJ memory cell array 10 are present in a center portion of the bit line BL, and the dummy cells DC arranged in the dummy cell array 11 are present on both sides of the center portion. The write current adjusting circuit 22E is coupled to a word line WL to which one dummy cell DC2 included in the dummy cell array 11 is coupled.

As illustrated in FIG. 18, the word line WL is electrically coupled to a control gate of the access transistor ATR of the dummy cell DC2. Accordingly, the reference voltage Vref_BL outputted by the write current adjusting circuit 22E is inputted into the control gate of the access transistor ATR via the word line WL.

In the dummy cell DC2, a fixed magnetic layer and a free magnetic layer of a magnetoresistive element MTJ is short-circuited. Accordingly, the write current IBL which flows through the bit line BL flows through the access transistor ATR via the short-circuited path formed in the magnetoresistive element MTJ. The current IL which flows through the access transistor ATR is adjusted by the reference voltage Vref_BL inputted into the control gate.

By adopting such a configuration, the write current IBL flows through the current path formed by the magnetoresistive element MTJ with the short-circuited magnetic layers in the dummy cell DC and the access transistor ATR, and the current amount thereof is adjusted by the change of a value of resistance of the current path according to the reference voltage Vref_BL. That is, the access transistor ATR of the dummy cell DC configures a “current adjusting transistor.”

In this way, by performing the adjustment of the write current IBL in units of bit lines by use of the access transistor ATR of the dummy cell DC which is arranged in order to secure the uniformity of the MTJ memory cell, it is possible to prevent the occupied area of the peripheral circuit from increasing due to having provided a write current adjusting circuit per bit line. As a result, it becomes possible to secure a write window, without increasing the occupied area of the MRAM circuit block.

### Modified Example

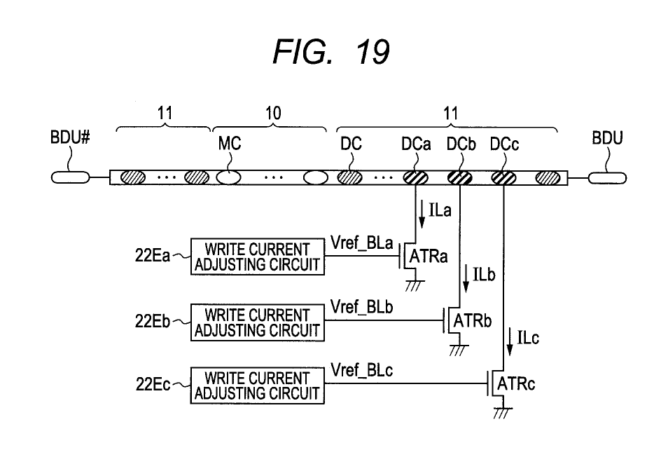

FIG. 19 illustrates an example of a configuration in which access transistors ATR of the plural dummy cells DC coupled to the bit line BL are utilized as a current adjusting transistor.

As illustrated in FIG. 19, write current adjusting circuits 22Ea, 22Eb, and 22Ec are respectively coupled, via the word line WL, to control gates of the access transistors ATRa to ATRc of three dummy cells DCa to DCc coupled to the bit line BL in common.

The write current adjusting circuit 22Ea, 22Eb, and 22Ec apply reference voltages Vref_BLa, Vref_BLb, and Vref_BLc to the control gates of the corresponding access transistors ATRa, ATRb, and ATRc, respectively. The currents ILa, ILb and ILc which flow through the access transistors ATRa, ATRb, and ATRc are adjusted by the reference voltage Vref_BLa, Vref_BLb, and Vref_BLc, respectively. The write current IBL is adjusted according to the sum of the adjusted currents ILa, ILb, and ILc.

According to the present modified example, it is possible to attain fine tuning of the write current IBL which flows through the bit line BL, by utilizing the access transistors ATR of the plural dummy cells DC as a current adjusting transistor. Accordingly, it is possible to improve the write margin.

### Embodiment 5

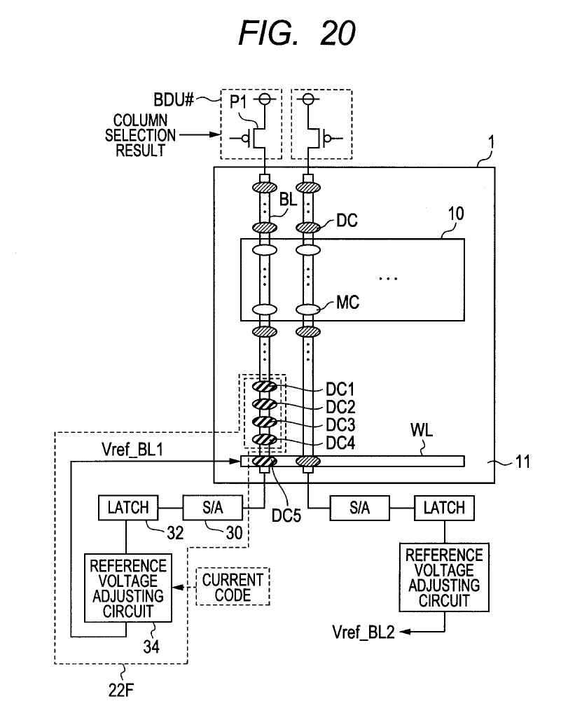

FIG. 20 is a schematic diagram illustrating a tuning operation of write current according to Embodiment 5 of the present invention. As illustrated in FIG. 1, the MRAM device according to Embodiment 5 includes the MTJ memory cell array 10 in which MTJ memory cells (normal memory cells) MC are arranged in a matrix, and dummy cells DC are provided in the peripheral area of the MTJ memory cell array 10, so as to continue the arrangement pattern of the normal memory cells MC.

In Embodiment 5, plural bit lines BL provided corresponding to each memory cell column are divided in units of at least one column, and the current amount of a write current IBL is adjusted for every division unit. FIG. 20 illustrates an example of the case in which plural bit lines BL are divided in units of one column and a write current adjusting circuit 22F is provided for every division unit.

The write current adjusting circuit 22F generates the reference voltage Vref_BL and outputs it to the corresponding bit line drive unit BDU, in each of the test mode and the normal mode. The write current adjusting circuit 22F includes a sense amplifier (S/A) 30, a latch circuit 32, a reference voltage adjusting circuit 34, and dummy cells DC1 to DC5. Among these, the dummy cells DC1 to DC4, the sense amplifier 30, and the latch circuit 32 configure a “tuning input unit” for inputting a setting value (current code) of the write current IBL, and the reference voltage adjusting circuit 34 and the dummy cell DC5 configure a “voltage adjusting unit” which adjusts the reference voltage Vref_BL on a bit line by bit line basis, according to the current code supplied from the tuning input unit.

The write current adjusting circuit 22F according to Embodiment 5 uses the dummy cells DC1 to DC4 as a program element which stores, in a nonvolatile manner, the current code obtained by the tuning test of the write current IBL in units of bit lines, and uses the dummy cell DC5 as a transistor for adjusting the write current IBL.

As explained in Embodiment 2, it is possible to store the current code in the dummy cells DC1 to DC4, for example, by destroying electrically with the application of a high voltage which exceeds a maximum rating to the dummy cell DC, according to a logical level of the current code. It is also possible to store the current code in the dummy cells DC1 to DC4, by changing the relative relation of a magnetization direction between a fixed magnetic layer and a free magnetic layer in the tunneling magnetoresistive element TMR included in the dummy cell DC.

As explained in Embodiment 4, in the dummy cell DC5, the fixed magnetic layer and the free magnetic layer of the magnetoresistive element MTJ are short-circuited, and the reference voltage Vref_BL outputted by the reference voltage adjusting circuit 34 is inputted to the control gate of the access transistor ATR. Accordingly, the write current IBL which flows through the bit line BL flows through the access transistor ATR via the short-circuited path formed in the magnetoresistive element MTJ. The current amount of the write current IBL is adjusted by the reference voltage Vref_BL inputted to the control gate of the access transistor ATR.

According to Embodiment 4, by adopting such a configuration, it is possible to make the dummy cell DC store a current code by performing the same processing as a data write to the normal memory cell MC. Furthermore, it is possible to adjust the write current, using the access transistor ATR of the dummy cell DC as a current adjusting transistor. Accordingly, it is possible to suppress the occupied area of the peripheral circuit to increase due to having provided a write current adjusting circuit per bit line. As a result, it becomes possible to secure a data write window, without increasing the occupied area of the MRAM circuit block.

(Configuration of a self test circuit) In Embodiments 1 to 5, a configuration has been explained in which at least one bit line BL or at least one digit line DL is treated as a division unit and tuning of a write current is performed for every division unit. The following explains an example of a configuration of a self test circuit for conducting the tuning test of a write current in each of the embodiment.

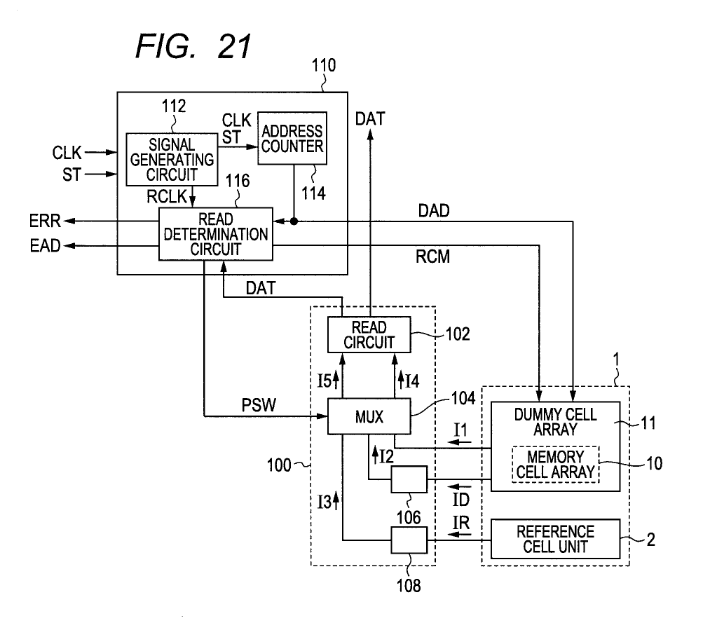

FIG. 21 illustrates a configuration of a self test circuit and explains a self test. As illustrated in FIG. 21, a memory array 1 includes a memory cell array 10, a dummy cell array 11, and a reference cell unit 2.

The reference cell unit 2 is provided for the purpose of generation of a reference current which serves as a comparison target to a data read current of the normal memory cell MC, in order to read data from the MTJ memory cell MC precisely in the tuning test of a write current. The reference cell unit 2 includes reference cells RC1 and RC2 (not shown) which have the same configuration as the normal memory cell MC. Corresponding to the reference cells RC1 and RC2, reference bit lines RBL1 and RBL2, and a digit line RDL are provided. At the time of data write to the reference cells RC1 and RC2, a signal RWC indicative of data write is supplied from a signal generating circuit 112 in a self test circuit 110. At the time of data write, by flowing currents of opposite directions with each other through the reference bit lines RBL1 and RBL2, “1” and “0” are written in the reference cells RC1 and RC2, respectively. At the time of a data read from the reference cells RC1 and RC2, a current halving circuit averages a current which flows through the reference bit line RBL1 and a current which flows through the reference bit line RBL2, to output a current I3.

A read/write control circuit 100 includes a read circuit 102, which is a sense amplifier, for example. The read circuit 102 reads data from the normal memory cell MC in each of the normal mode and the test mode. In the normal mode, the read circuit 102 compares a value of current which flows through a bit line coupled to the selected normal memory cell MC, with a value of current which flows through two bit lines respectively coupled to two dummy cells DC corresponding to the selected normal memory cell MC, and determines data which is read from the normal memory cell MC. In the test mode, the read circuit 102 compares a value of current which flows through the bit line coupled to the selected normal memory cell MC, with a value of current which flows from the reference cell unit 2, and determines data which is read from the normal memory cell MC.

The read/write control circuit 100 includes further a multiplexer (MUX) 104, a current halving circuit 106, and a current halving circuit 108. The multiplexer (MUX) 104 switches a current to be outputted to the read circuit 102 according to a signal PSW. The current halving circuit 106 outputs a current I2 obtained by reducing by half a current ID which flows through the dummy cell array 11, for the purpose of generation of a reference current which is necessary at the time of a read from the normal memory cell MC in the normal mode. The current halving circuit 108 outputs a current I3 obtained by reducing by half a current IR which flows through the reference cell unit 2, for the purpose of generation of a reference current which is necessary at the time of a read from the normal memory cell MC in the test mode.

In the test mode, the self test circuit 110 generates an address signal DAD for selecting the normal memory cells MC one by one, and detects a bad memory cell according to the comparison result between the data read from the normal memory cell MC and the data of an expectation value. The self test circuit 110 includes an address counter 114, a signal generating circuit 112, and a read determination circuit 116.

The address counter 114 updates (increments) a count value according to a clock CLK, and generates an address signal DAD. The test can be automatically performed by providing the address counter 114. The signal generating circuit 112 outputs a signal RWC for instructing data write to the reference cell unit 2 at the start of the tuning test in response to a signal ST. The read determination circuit 116 outputs the signal PSW to the MUX 104 at the start of the tuning test, for the MUX 104 to switch the current to output.

The signal ST is generated by a power-on detection circuit (not shown) which detects that a power supply potential has been supplied (the power supply has been set to ON) to the MRAM device. The signal ST generated is inputted to the self test circuit 110. Upon detecting that the power supply has been set to ON, the power-on detection circuit instructs the self test circuit 110 to execute the test. The clock CLK may be an external clock, or may be a clock generated inside according to an external clock.

In the normal mode, according to the signal PSW, the MUX 104 outputs a current I1 to the read circuit 102 as a current I4 indicating the read data, and outputs a current I2 as a current I5 indicating the reference current. In the test mode, the MUX 104 switches the current to be outputted as the current I5 according to the signal PSW; namely, the MUX 104 outputs a current I1 as the current I4 indicating the read data, and outputs a current I3 as the current I5 indicating the reference current.

The read determination circuit 116 receives a read trigger signal RCLK, an address signal DAD, and read data DAT. The read determination circuit 116 compares the data DAT with an expectation value and determines whether the normal memory cell MC is normal or abnormal. The read determination circuit 116 outputs a signal ERR indicating that a bad memory cell has been detected, and an address signal EAD for specifying the bad memory cell.

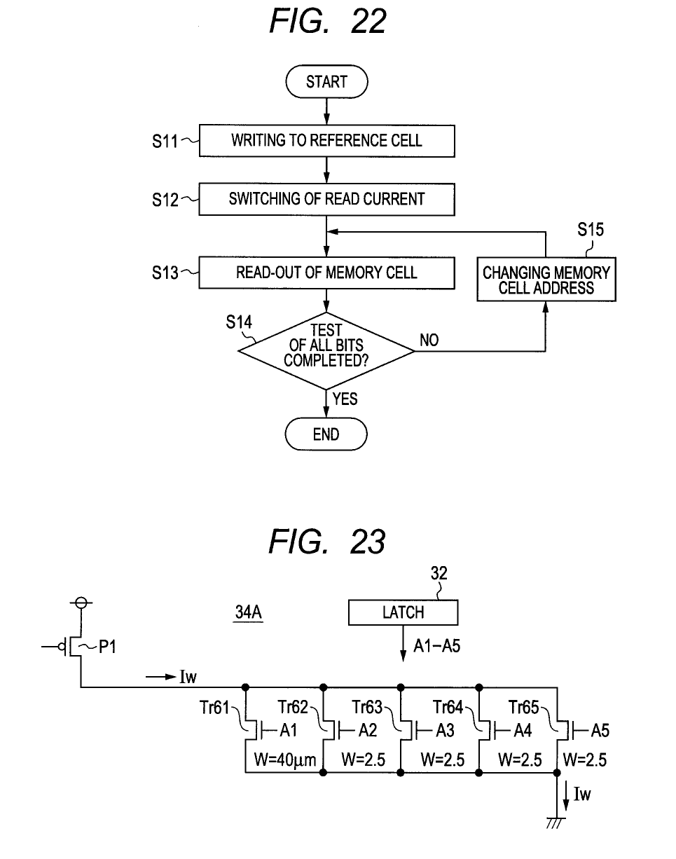

FIG. 22 is a flow chart explaining a tuning test process of write current by means of the self test circuit 110 illustrated in FIG. 21.

As illustrated in FIG. 22, when processing is started, at Step S11, the power-on detection circuit detects that a power supply has been turned on, and outputs a signal ST to the self test circuit 110. When the signal ST is inputted to the signal generating circuit 112 in the self test circuit 110, the signal generating circuit 112 outputs a signal RWC for writing in the reference cells RC1 and RC2. The signal generating circuit 112 outputs the signal RWC for instructing the control circuit to perform data write to the reference cells RC1 and RC2, in response to the signal ST and the clock CLK.

When the data write to the reference cell is completed, at Step S12, the self test circuit 110 sends a signal PSW for instructing the MUX 104 to switch the current which the MUX 104 outputs. Upon receiving the signal PSW, the MUX 104 switches the current to the read circuit 102 so that the MUX 104 outputs the current I1 from the memory cell array 10 as the read current (current I4), and outputs the current I3 from the current halving circuit 108 as the reference current (current I5).

At Step S13, a read of data from the MTJ memory cell MC included in the division unit as the test target is performed. The address counter 114 outputs an address signal DAD according to the clock CLK. Synchronizing with the operation of the address counter 114, the read determination circuit 116 outputs a read signal RCM. According to the address signal DAD and the read signal RCM, the current I1 is outputted from the memory cell array 10, and the current I3 is outputted from the current halving circuit 108. These currents are inputted into the read circuit 102 via the MUX 104, and the data DAT is outputted from the read circuit 102.

The address signal DAD and the data DAT are inputted to the read determination circuit 116. The read determination circuit 116 compares the data read from the MTJ memory cell MC with the expectation value, and determines whether the data stored in the MTJ memory cell MC is normal or not. When the data stored in the MTJ memory cell MC differs from the expectation value, the read determination circuit 116 sends to the control circuit a signal ERR and an address signal EAD which specifies the address of the bad memory cell.

At Step S14, when the test is completed to all the MTJ memory cells MC included in the division unit as the test target (YES at Step S14), the entire processing is completed. On the other hand, when the test has not been completed yet (NO at Step S14), the address counter 114 outputs the address signal DAD for changing the address of the MTJ memory cell MC, at Step S15. After processing at Step S15 is completed, processing returns to Step S13.

The tuning of a write current for every division unit is performed by performing such a series of operations, changing the division unit as the test target. When the tuning of a write current is completed in all the division units, the MRAM circuit block is brought into a standby state.

(Modified example of a reference voltage adjusting circuit) FIG. 23 is a drawing explaining a modified example of the reference voltage adjusting circuit illustrated in FIG. 13.

As illustrated in FIG. 23, a reference voltage adjusting circuit 34A according to the present modified example is different from the reference voltage adjusting circuit 34 illustrated in FIG. 13 in the point that the reference voltage adjusting circuit 34A includes plural N-channel MOS transistors Tr61 to Tr65 which are coupled in parallel between the constant current source 342 and the ground voltage, in lieu of the plural resistors R1 to R4 which are coupled in series between the constant current source 342 and the ground voltage.

The plural N-channel MOS transistors Tr61 to Tr65 are designed to have a ratio of gate width W as 40:2.5:2.5:2.5:2.5, for example. The respective gates of the N channel each MOS transistors Tr61 to Tr65 are driven to an H level or an L level, according to the current code inputted from the latch circuit 32. Accordingly, the constant current Iw supplied by the constant current source 342 is shunted among the N-channel MOS transistors which are shifted from an off state to an on state. At this time, the value of resistance of the current path which goes from the constant current source 342 to the ground voltage can be set variably by changing the N-channel MOS transistors which are shifted to an on state. Consequently, a voltage corresponding to the product of the value of resistance and the constant current Iw is applied to the gate of the N-channel MOS transistor N2, as the reference voltage Vref_BL. As a result, the write current IBL corresponding to the current code programmed to the dummy cells DC1 to DC4 flows through the bit line BL.

It should be understood by those skilled in the art that the embodiments disclosed in the present application are illustrative and not restrictive, with all the points of view. The scope of the present invention is illustrated not by the explanatory description of the embodiments given above but the scope of the appended claims, and it is meant that various modifications, combinations, and alterations may occur depending on design requirements and other factors insofar as they are within the scope of the appended claims or the equivalents thereof.

What is claimed is:

1. A semiconductor device comprising:
a plurality of memory cells arranged in a matrix and each operable to store data in a nonvolatile manner;
a plurality of first write current lines arranged corresponding to columns of the memory cells;
a plurality of second write current lines arranged corresponding to rows of the memory cells;
a write current adjusting unit operable to adjust a current amount of write current to be flowed through at least one of the first write current lines and the second write current lines, in order to perform data write normally to each of the memory cells;
a first write circuit electrically coupled to the first write current lines; and
a second write circuit electrically coupled to the second write current lines,
wherein at least one of the first write circuit and the second write circuit writes data in each of the memory cells, by flowing write current through at least one of the first write current lines and the second write current lines based on the current amount adjusted by the write current adjusting unit, and
wherein the write current adjusting unit divides at least one of the first write current lines and the second write current lines into units of at least one write current line as division units, and includes a plurality of write current adjusting circuits operable to adjust the current amount of write current in each of the division units concerned.

2. The semiconductor device according to claim 1, further comprising:
a plurality of dummy cells arranged continuously with the memory cells,
wherein each of the memory cells includes a magnetic memory element,
wherein each of the dummy cells includes a dummy magnetic memory element which is designed in the same structure as the magnetic memory element, and
wherein each of the write current adjusting circuits stores the adjusted current amount of write current to the dummy magnetic memory element of each of the dummy cells, in a nonvolatile manner.

3. The semiconductor device according to claim 2,
wherein, in the dummy magnetic memory element, electric resistance changes corresponding to a magnetization direction which changes corresponding to a magnetic field applied, and
wherein each of the write current adjusting circuits stores the current amount of the write current by means of combination of electric resistance of the dummy magnetic memory elements.

4. The semiconductor device according to claim 1, further comprising:
a plurality of dummy cells arranged continuously with the memory cells,
wherein each of the memory cells includes a magnetic memory element and an access element operable to pull down the magnetic memory element to a ground voltage at the time of data read,
wherein each of the dummy cells includes a dummy magnetic memory element and a dummy access element which are designed in the same structure as the magnetic memory element and the access element, respectively, and
wherein each of the write current adjusting circuits includes a reference voltage adjusting circuit operable to input to a gate of the dummy access element a reference voltage to be used for applying the write current of the adjusted current amount to at least one of the first write current line and the second write current line, in a state where the dummy magnetic memory element is short-circuited.

5. The semiconductor device according to claim 1, having a normal operation mode and a test mode which adjusts the current amount of write current for the division units, and further comprising:
a test circuit operable to execute the test mode, when it is detected that a power supply potential is supplied to the semiconductor device.
